(19) United States
(12) Patent Application Publication
(10) Pub. No.: US 2010/0014259 A1
(43) Pub. Date: Jan. 21, 2010

(54) MODULAR CIRCUIT BOARD STRUCTURE FOR LARGE CURRENT AREA

(75) Inventor: Cheng Po Huang, Sanchong City (TW)

Correspondence Address: APEX JURIS, PLLC, 12733 LAKE CITY WAY NORTHEAST, SEATTLE, WA, 98125, US

(73) Assignee: ENERMAX TECHNOLOGY CORPORATION, Taoyuan City (TW)

(21) Appl. No.: 12/173,230

(22) Filed: Jul. 15, 2008

(51) Int. Cl. H05K 1/14

(52) U.S. Cl. 361/736

(57) ABSTRACT

A modular circuit board structure for a large current area includes a circuit board having an electric conducting circuit and at least one large current area, and a conducting plate device having conducting plates installed onto the circuit board according to the shape of the large current area. When electronic components are inserted onto the circuit board by a surface mount technology, the conducting plates are attached onto the large current area to form a solder area portion on the conducting plates for allowing a large current to pass through, so as to provide a flexible combination function for the large current area of the circuit board and simplify the stamping molds of different shapes. The invention can avoid a waste of copper plates, assure the reliability, quality and safety of the circuit board, and enhance the cost effectiveness of the manufacture and the competitiveness of the product.

### BACKGROUND OF THE INVENTION

1. Field of the Invention

The present invention relates to a circuit board structure, and more particularly to a modular circuit board structure for a large current area used for passing a larger current, and the structure comes with a simple, easy, flexible and cost-effective way of manufacturing a circuit board.

2. Description of the Related Art

Circuit board has become a primary carrier for general electronic or electric appliance products. Since the circuit board usually includes complicated electric conducting circuits and various types of electronic components for passing electric currents and various types of signals to achieve the expected functions. To meet the requirements of the operation of an electronic device, the circuit board includes a certain area for passing a larger current. For example, the circuit board of a power supply device has a certain area for passing a large current (such as a power supply structure of a solenoid driver). Therefore, a certain area of the circuit board is usually reserved for passing a larger current for the operation of the related equipment. Referring to FIG. 1 for a circuit board structure of a prior art, the structure includes a circuit board 70, and the circuit board 70 includes an electric conducting circuit 71 (such as a copper foil circuit) for electrically coupling various related electronic components (not shown in the figure). The circuit board 70 has a large current area 72 for installing a copper foil 73 substantially in a similar shape, and the copper foil 73 goes through a surface mount technology (SMT) or a soldering process to fix the copper foil 73 onto the circuit board 70, and the copper foil 73 is provided for achieving the effect of passing a larger current.

Referring to FIG. 2 for a schematic view of a circuit board having a large current area in accordance with a prior art, the prior art includes a circuit board 80, and the circuit board 80 includes an electric conducting circuit 81 (such as a copper foil circuit), and the electric conducting circuit 81 is installed and electrically coupled to various related electronic components (not shown in the figure), and the circuit board 80 includes a large current area 82. After the circuit board 80 goes through a component insertion and a soldering furnace of the surface mount technology (SMT), the large current area 82 is soldered to form a large and thick solder area portion 83 by soldering manually and slowly, such that the solder area portion 83 allows the distribution of a large current. However, such two-time manual manufacture of the prior art has the following drawbacks: (1) The number of man-hours is increased; (2) If the manual manufacture continues, the temperature of the soldering iron will rise, and the time of the soldering iron remained at the soldering position will be too long, and thus the heat may damage the peripheral components easily; (3) The manual processing may cause a solder overfill or a short circuit easily; and (4) The appearance looks bad or a poor texture results after the manual manufacture.

Referring to FIG. 3 for a schematic view of a circuit board having a large current area in accordance with another prior art, the prior art includes a circuit board 90, and the circuit board 90 also includes an electric conducting circuit 91 (such as a copper foil circuit) and a large current area 92; and the large current area 92 is manufactured with a copper plate 93 in a similar shape in advance, and the copper plate 93 is installed onto the large current area 92 correspondingly. After the circuit board 90 goes through the component insertion of the surface mount technology (SMT) to automatically solder the copper plate 93, a larger and thicker solder area portion 94 is formed and fixed onto the large current area 92, such that the copper plate 93 and the solder area portion 94 can pass a large current. However, such prior art still has the following drawbacks: (1) Since the shape of the area of each circuit board for passing a large current (which is the large current area 92) is different, the cost for stamping and molding the copper plate is increased; (2) After the copper plate 93 is stamped and molded, the nearby area around the copper plate 93 cannot be used, and such area is thus wasted. Therefore, it is a subject for manufacturers and designers to overcome the drawbacks of the circuit board having the large current area in accordance with the aforementioned prior arts.

In view of the forgoing shortcomings of the prior art, the inventor of the present invention based on years of experience in the related industry to conduct extensive researches and experiments, and finally developed a convenient, economic and flexible circuit board structure with a large current area to overcome the shortcomings and promote the development of the related industry.

### SUMMARY OF THE INVENTION

The primary objective of the present invention is to overcome the shortcomings of the prior art by providing a modular circuit board structure for a large current area, such that a circuit board has a convenient, economic and flexible large current area to avoid wasting copper plates and achieve the effect of enhancing the economic benefits of the application and the competitiveness of the product.

Another objective of the present invention is to provide a modular circuit board structure for a large current area, such that a circuit board comes with a large current area for providing a better safety, avoiding damages to peripheral components and preventing a short circuit, so as to assure the reliability, quality and safety of the circuit board.

To achieve the foregoing objectives, the present invention provides a modular circuit board structure, comprising: a circuit board, having an electric conducting circuit, and at least one large current area disposed on said circuit board; and a conducting plate device, having a plurality of conducting plates disposed on the large current area according to a puzzle combination of the large current area; such that when electronic components are inserted onto the circuit board by surface mount technology, the plurality of conducting plates are attached onto said large current area at the same time.

The plurality of conducting plates can be copper plates produced in a mass quantity in advance and stamped into different shapes and sizes to fit different shapes of the large current area of the circuit board, and an appropriate number of conducting plates is selected for a puzzle combination to fit the required shape for passing a large current through the large current area, and the conducting plates are attached onto the large current area through the SMT process to achieve the effect of minimizing the manufacturing cost.

To make it easier for our examiner to understand the objects, shape, characteristics and performance of the present invention, we used preferred embodiments accompanied with related drawings for the detailed description of the invention as follows.

### BRIEF DESCRIPTION OF THE DRAWINGS

FIG. 1 is a schematic view of a circuit board having an apparatus for passing a larger current in accordance with a prior art;

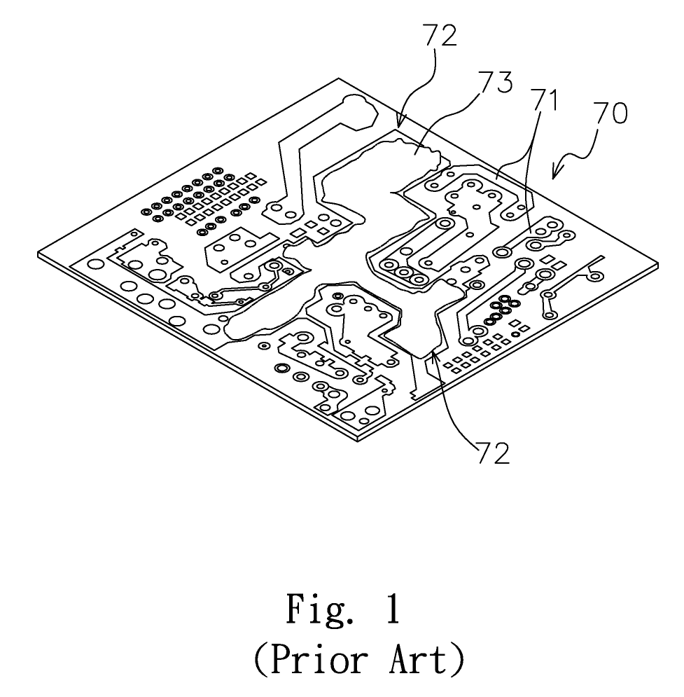

FIG. 2 is a schematic view of circuit board having a large current area in accordance with a prior art;

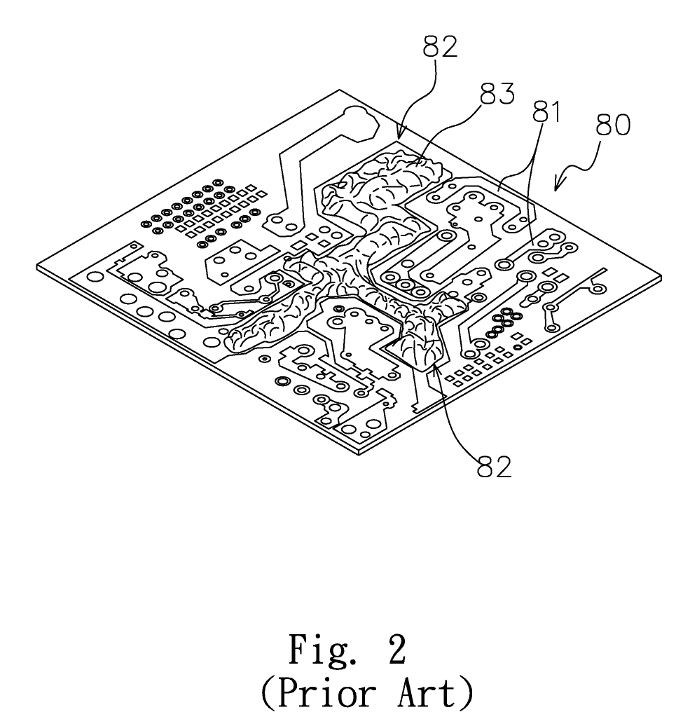

FIG. 3 is a schematic view of circuit board having a large current area in accordance with another prior art;

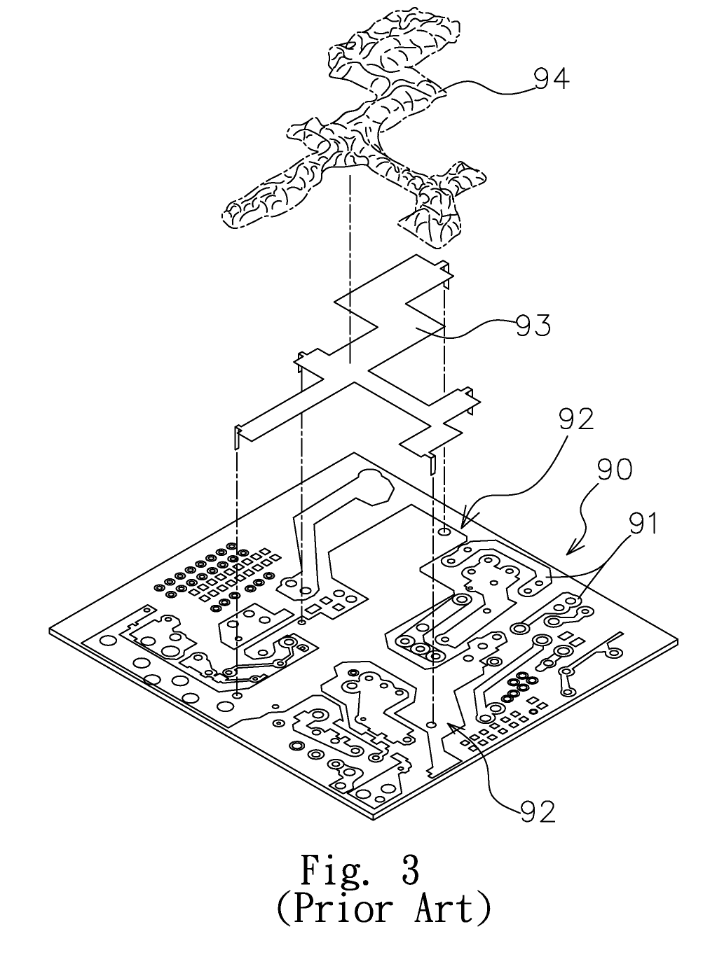

FIG. 4 is a schematic view of a first preferred embodiment of the present invention; and

FIG. 5 is a schematic view of a second preferred embodiment of the present invention.

### DETAILED DESCRIPTION OF THE PREFERRED EMBODIMENTS

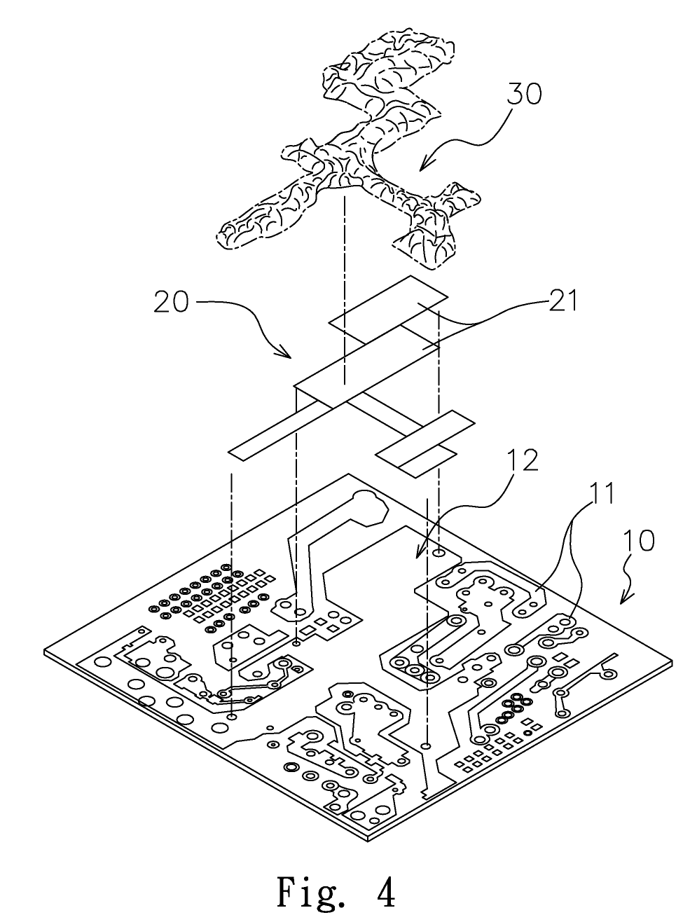

Referring to FIG. 4 for a schematic view of a modular circuit board structure for a large current area in accordance with a first preferred embodiment of the present invention, the structure comprises a circuit board 10, and the circuit board 10 includes an electric conducting circuit 11 (such as a copper foil circuit) for electrically coupling various related electronic components (not shown in the figure), and the circuit board 10 has a large current area 12 for passing a large current; a conducting plate device 20 including a plurality of conducting plates 21 (such as copper plates), and the plurality of conducting plates 21 are stamped into plates of different geometric shapes. During installation, the plurality of conducting plates 21 are combined with the large current area 12 according to the shape of the large current area 12. After the circuit board 10 goes through the component insertion and soldering furnace of the surface mount technology (SMT), the conducting plate device 20 is attached onto the large current area 12 at the same time to form a larger and thicker solder area portion 30 on the conducting plate device 20, and thus the manufacture only requires a one-time soldering process to complete manufacturing the large current area, and the conducting plate device 20 and the solder area portion 30 allow a large current to pass through.

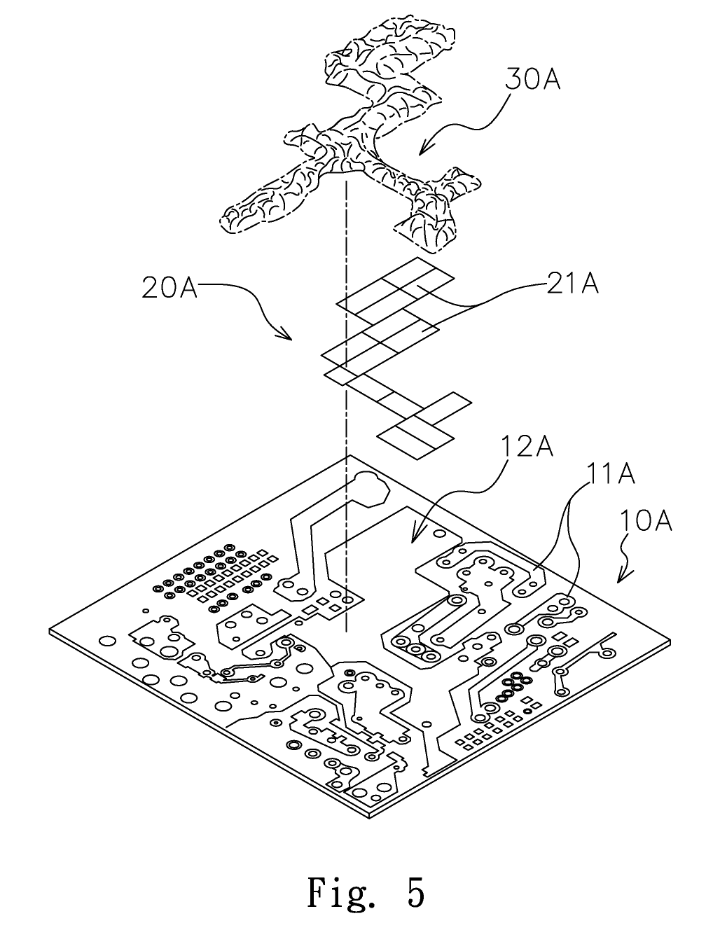

Referring to FIG. 5 for a schematic view of a modular circuit board structure for a large current area in accordance with a first preferred embodiment of the present invention, the structure comprises a circuit board 10A and a conducting plate device 20A. The circuit board 10A includes an electric conducting circuit 11A (which is a copper foil circuit) for electrically coupling various related electronic components (not shown in the figure), and the circuit board 10A includes a large current area 12A. The conducting plate device 20A includes a plurality of conducting plates 21A (such as copper plates), and the plurality of conducting plates 21A are mass produced into plates in different geometric shapes by stamping in advance. The difference of this preferred embodiment and the first preferred embodiment resides on that the large current area 12A and the large current area 12 have different shapes, so that the plurality of conducting plates 21A can be combined flexibly to fit a combination of shapes of the large current area 12A (or other large current areas of different shapes). Similarly, during installation, the plurality of conducting plates 21A can be combined according to the shape of the large current area 12A and installed onto the large current area 12A. After the circuit board 10A goes through the component insertion and soldering furnace of the surface mount technology (SMT), the conducting plate device 20A is attached onto the large current area 12A at the same time to form a larger and thicker solder area portion 30A on the conducting plate device 20A, so that the manufacturing process only requires a one-time soldering process to complete the large current area, and the conducting plate device 20A and the solder area portion 30A allow a large current to pass through.

The present invention uses a separate design of the conducting plate device to achieve a flexible combination of the large current area and complete the large current area by going through the component insertion and soldering furnace of the surface mount technology (SMT) for one time only. The separate design of the conducting plate device can fit a combination of shapes of the large current areas in different shapes, such that the stamping and molding processes can be simplified. The invention has the advantages of saving costs, providing a flexible installation, and avoiding a waste of copper plates. Meanwhile, the present invention also provides a safe and large current area of the circuit board and prevents damages or short circuits to the electronic components adjacent to the large current area to assure the reliability, quality and safety of the circuit board. The overall practicability and product competitiveness of the circuit board can be enhanced.

In summation of the above description, the present invention herein enhances the performance of the conventional structures and further complies with the requirements of patent application and is thus duly filed for the patent application.

While the invention has been described by means of specific embodiments, numerous modifications and variations could be made thereto by those skilled in the art without departing from the scope and spirit of the invention set forth in the claims.

What is claimed is:

1. A modular circuit board structure for a large current area, comprising:
a circuit board, having an electric conducting circuit, and at least one large current area disposed on said circuit board; and
a conducting plate device, having a plurality of conducting plates disposed on said large current area according to a puzzle combination of said large current area;
such that when components are inserted onto said circuit board by a surface mount technology, said plurality of conducting plates are attached onto said large current area.

2. The modular circuit board structure for a large current area according to claim 1, wherein said plurality of conducting plates form a solder area portion for allowing a large current to pass through after said components are inserted by the surface mount technology.

3. The modular circuit board structure for a large current area according to claim 1, wherein said electric conducting circuit is a copper foil circuit.

4. The modular circuit board structure for a large current area according to claim 1, wherein said plurality of conducting plates are plates in different geometric shapes.

5. The modular circuit board structure for a large current area according to claim 4, wherein said plurality of conducting plates are formed into plates in different geometric shapes by a stamping method.

6. The modular circuit board structure for a large current area according to claim 2, wherein said solder area portion is an area portion with a larger and thicker area.
